(19) United States
(12) Patent Application Publication
(10) Pub. No.: US 2007/0145486 A1
(43) Pub. Date: Jun. 28, 2007

(54) Semiconductor memory device and method of manufacturing the same

(75) Inventor: Eiji Hasunuma, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/644,839

(22) Filed: Dec. 26, 2006

(30) Foreign Application Priority Data
Dec. 27, 2005 (JP) 2005-375412

(51) Int. Cl. H01L 29/76

(52) U.S. Cl. 257/365

(57) ABSTRACT

A semiconductor memory device has a memory cell and a peripheral transistor formed on a substrate. The memory cell is provided with a select transistor formed on the substrate and a capacitor connected to the select transistor. A diffusion layer of the peripheral transistor is connected to an upper layer interconnection through a first contact. Gate electrodes of the peripheral transistor and the select transistor are connected to upper layer interconnections through respective of second contacts. A diffusion layer of the select transistor is connected to any of a bit line and the capacitor through a third contact. Silicide is selectively formed only in the first contact out of the first contact, the second contacts and the third contact.

### BACKGROUND OF THE INVENTION

1. Field of the Invention

The present invention relates to a semiconductor memory device. In particular, the present invention relates to a semiconductor memory device to which a salicide technique is applied.

2. Description of the Related Art

Silicide with low resistivity, high heat resistance and high oxidataion resistance is produced by reacting silicon and metal at high temperature. In a DRAM or a microcomputer with a built-in DRAM, a salicide technique in which the silicide is formed at a bottom of a contact hole is often employed for the purpose of suppressing a contact resistance (for example, refer to Japanese Laid Open Patent Application JP-P2003-289131). A process of manufacturing a conventional DRAM having a salicide structure is described below with reference to FIGS. 1 to 4.

Referring to FIG. 1, an isolation structure 102 such as an STI (Shallow Trench Isolation) and the like is formed in a substrate 101. After that, gate electrodes 103 are formed on the substrate 101 through gate insulating films. The gate electrodes 103 include a gate electrode of a select transistor included in a DRAM cell and a gate electrode of a peripheral transistor included in a logic circuit. The gate electrode 103 has a polycide gate structure consisting of polysilicon and WSi (tungsten silicide). After that, a source/drain diffusion layer 104 of the select transistor and a source/drain diffusion layer 105 of the peripheral transistor are formed in the substrate 101 by using the gate electrodes 103 as a mask.

Next, an interlayer insulating film 107 is blanket deposited. Then, a cell contact plug 106 is formed on the source/drain diffusion layer 104 of the select transistor in the DRAM cell. The cell contact plug 106 is made of doped polysilicon or doped amorphous silicon. The cell contact plug 106 is a part of a plug for connecting between the source/drain diffusion layer 104 and a capacitor of the DRAM cell or between the source/drain diffusion layer 104 and a bit line.

Next, an interlayer insulating film 107 is further blanket deposited so as to cover the cell contact plug 106. After that, a first contact hole C1, a second contact hole C2 and a third contact hole C3 are formed by using the photolithography technique. More specifically, after a resist mask having a predetermined pattern is formed on the interlayer insulating film 107, the interlayer insulating film 107 in a predetermined region is removed by dry etching. As a result, the first contact hole C1 contacting the source/drain diffusion layer 105 is formed in a region where the peripheral transistor is formed. Moreover, the second contact hole C2 contacting the gate electrode 103 is formed. Furthermore, the third contact hole C3 contacting the cell contact plug 106 is formed in a region where the DRAM cell is formed.

Next, in order to reduce a contact resistance, CoSi (cobalt silicide) is formed at a bottom of each of the first to third contact holes C1 to C3. More specifically, as shown in FIG. 2, a Co film 110 is blanket deposited by a sputtering method. Moreover, in order to prevent oxidation of the Co film 110, a Ti film 111 is blanket deposited as a cap film. Next, a heat treatment at a temperature of about 400 degrees centigrade is performed, and thereby a silicide reaction occurs. When the remaining Co film 110 and the Ti film 111 as the cap film are removed by using mixed acid and the like, the structure shown in FIG. 3 is obtained. In FIG. 3, CoSi 121, 122 and 123 are formed at bottoms of the first contact hole C1, the second contact hole C2 and the third contact hole C3, respectively. It should be noted that if a polymetal gate (W/WN/poly, W/TiN/poly etc.) is used as the gate electrode 103 instead of the polycide gate, the CoSi 122 is not formed on the gate electrode 103.

Next, as shown in FIG. 4, the contact hole C1 in the peripheral transistor region is filled with a first contact plug 131 connected to an upper layer interconnection. Moreover, the contact hole C2 on the gate electrode 103 is filled with a second contact plug 132. Furthermore, the contact hole C3 on the cell contact plug 106 of the select transistor is filled with a third contact plug 133 connected to the bit line or the capacitor of the DRAM cell. Each of the first to third contact plugs 131 to 133 has a lamination structure of W/TiN/Ti.

### SUMMARY OF THE INVENTION

The present invention has recognized the following points. As shown in FIGS. 2 and 3, the depth of the contact hole C3 on the cell contact plug 106 is smaller than the depth of the other contact holes C1 and C2. Therefore, the amount of the Co film 110 formed in the contact hole C3 tends to be larger than that in the other contact holes C1 and C2. As a result, “aggregation” is likely to occur in the silicide reaction at the bottom of the contact hole C3. The “aggregation” is a phenomenon that silicide grows in an island-form due to the heat treatment and nonuniformity/discontinuity is generated. It is known that the occurrence of the aggregation causes rapid increase in the interconnection resistance with decreasing the interconnection width (thin line effect). In this manner, the CoSi 123, which is formed for the purpose of reducing the contact resistance, may possibly cause the increase in the contact resistance by contraries.

Moreover, according to the conventional technique, the CoSi 122 is formed at the bottom of the contact hole C2 if the polycide gate (polysilicon, WSi) is used as the gate electrode 103. When the second contact plug 132 is formed as shown in FIG. 4, a lamination structure of “W/TiN/TiSi/CoSi/WSi” is consequently formed in the gate electrode region. In this case, the number of interfaces is increased as compared with a case where the CoSi 122 is not formed. The increase in the number of interfaces causes increase in the contact resistance.

As described above, the process of forming CoSi at the bottom of the contact hole can reduce the contact resistance of the peripheral transistor, while can possibly increase the contact resistance of the select transistor. It is desired to reduce the contact resistance as a whole.

It is therefore an object of the present invention to provide a semiconductor memory device and a method of manufacturing the same that can reduce the contact resistance.

In a first aspect of the present invention, a semiconductor memory device is provided. The semiconductor memory device has a memory cell formed on a substrate and a peripheral transistor formed on the substrate. The memory cell is provided with a select transistor formed on the substrate and a capacitor connected to the select transistor. A diffusion layer of the peripheral transistor is connected to an upper layer interconnection through a first contact. Gate electrodes of the peripheral transistor and the select transistor are connected to upper layer interconnections through respective of second contacts. A diffusion layer of the select transistor is connected to any of a bit line and the capacitor through a third contact. According to the present invention, silicide is selectively formed only in the first contact out of the first contact, the second contacts and the third contact.

The above-mentioned silicide is formed at a bottom of the first contact. The silicide is, for example, cobalt silicide.

The above-mentioned third contact includes a first plug formed on the diffusion layer of the select transistor and a second plug formed on the first plug without through the silicide. A surface of the substrate is located nearer to a bottom of the first contact than to a bottom of the second plug.

In a second aspect of the present invention, a method of manufacturing a semiconductor memory device is provided. The manufacturing method has: (A) forming a select transistor of a memory cell and a peripheral transistor on a substrate; (B) forming a first plug on a diffusion layer of the select transistor; (C) blanket depositing an interlayer insulating film; (D) forming a first contact hole contacting a diffusion layer of the peripheral transistor, second contact holes contacting respective gate electrodes of the select transistor and the peripheral transistor, and a third contact hole contacting the first plug, by etching the interlayer insulating film; and (E) selectively forming silicide at a bottom of only the first contact hole out of the first contact hole, the second contact holes and the third contact hole. The silicide is, for example, cobalt silicide.

The above-mentioned (E) process may include: (a) blanket depositing a metal film as a material of the silicide; (b) selectively forming a resist mask over the first contact hole; (c) selectively removing the metal film through an etching using the resist mask; and (d) forming the silicide at a bottom of the first contact hole through a heat treatment.

The above-mentioned (E) process may include: (a) blanket depositing a metal film as a material of the silicide; (b) blanket coating the metal film with positive resist; (c) performing an exposure process such that light reaches only bottoms of the second contact holes and the third contact hole out of the first contact hole, the second contact holes and the third contact hole; (d) selectively forming a resist mask only in the first contact hole by removing the positive resist which is irradiated with the light; (e) selectively removing the metal film through an etching using the resist mask; and (f) forming the silicide at a bottom of the first contact hole through a heat treatment.

Hole diameters of the first contact hole, the second contact hole and the third contact hole are r1, r2 and r3, respectively. Depths of the first contact hole, the second contact hole and the third contact hole are t1, t2 and t3, respectively. The above-mentioned (E) process may include: (a) blanket depositing a metal film as a material of the silicide; (b) removing a part of the metal film by performing a sputter etching while tilting a wafer by an angle θ from a horizontal plane; and (c) forming the silicide at a bottom of the first contact hole through a heat treatment. Here, the angle θ satisfies the following equation: r1/t1<tan θ≦r2/t2≦r3/t3.

The manufacturing method according to the present invention further has: (F) filling the first contact hole with a plug connecting between the silicide and an upper layer interconnection; (G) filling respective of the second contact holes with plugs connecting between the gate electrodes and upper layer interconnections; and (H) filling the third contact hole with a second plug connecting between the first plug and a capacitor of the memory cell.

According to the present invention, as described above, the silicide is selectively formed only in the first contact hole out of the first contact hole, the second contact hole and the third contact hole. As a result, the contact resistance of the first contact connected to the diffusion layer of the peripheral transistor is reduced. Moreover, the silicide is not formed at the bottom of the second contact hole contacting the gate electrode. Therefore, the increase in the contact resistance due to the increase in the number of interfaces can be prevented. Furthermore, the silicide is not formed at the bottom of the third contact hole. Therefore, the increase in the contact resistance due to the aggregation can be prevented. In this manner, it is possible to reduce the contact resistance as a whole according to the present invention.

According to the semiconductor memory device and the manufacturing method thereof in the present invention, it is possible to reduce the contact resistance as a whole.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a process of manufacturing a conventional semiconductor memory device;

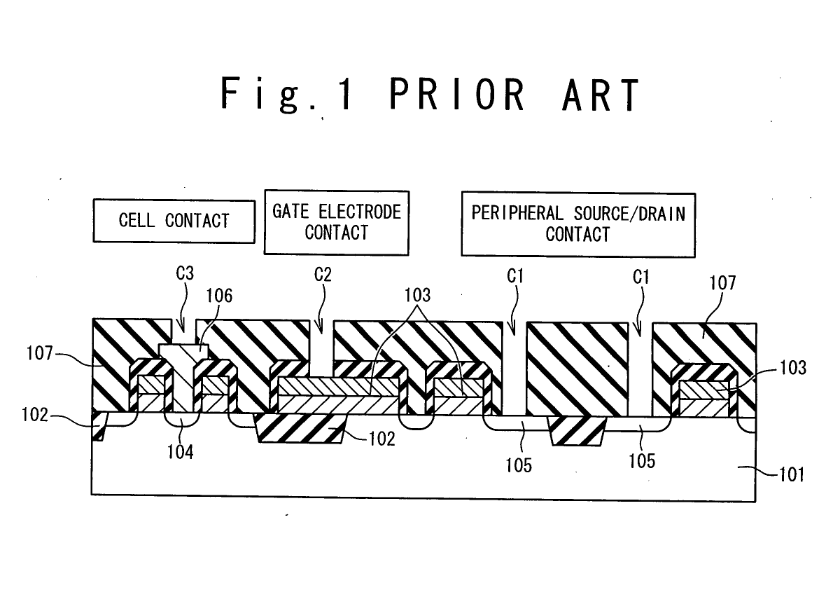

FIG. 2 is a cross-sectional view showing a process of manufacturing the conventional semiconductor memory device;

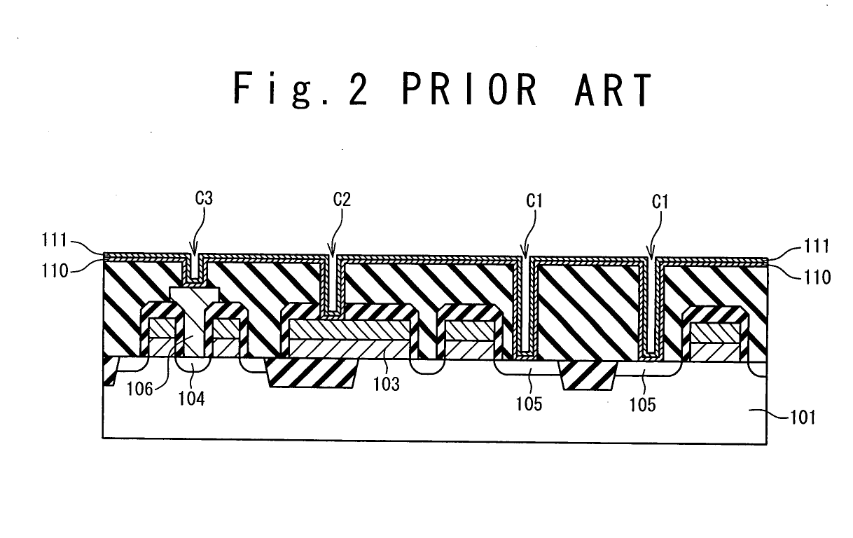

FIG. 3 is a cross-sectional view showing a process of manufacturing the conventional semiconductor memory device;

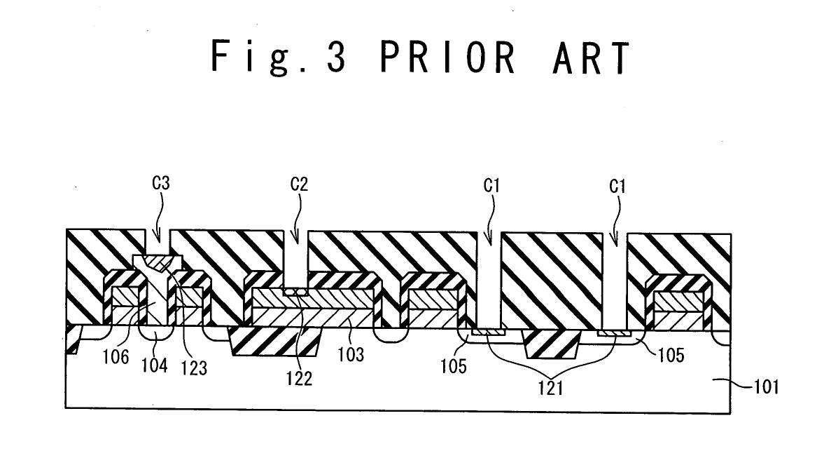

FIG. 4 is a cross-sectional view showing a process of manufacturing the conventional semiconductor memory device;

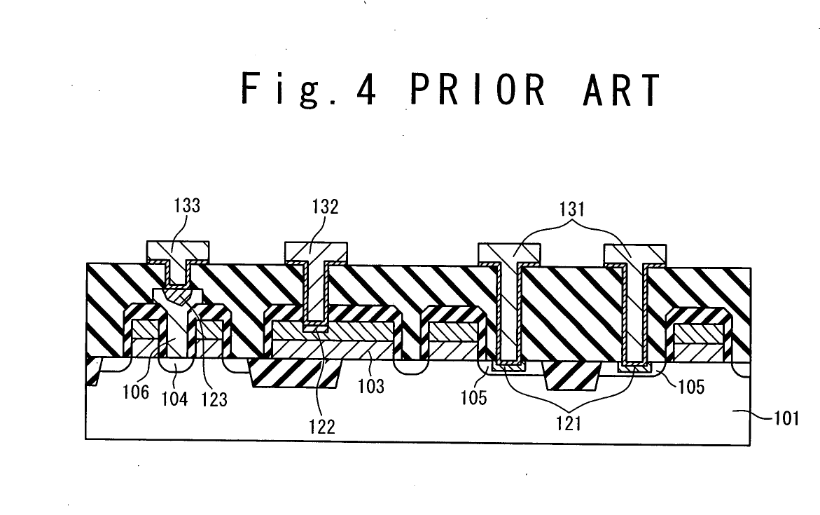

FIG. 5 is a cross-sectional view showing a process of manufacturing a semiconductor memory device according to a first embodiment of the present invention;

FIG. 6 is a cross-sectional view showing a process of manufacturing the semiconductor memory device according to the first embodiment;

FIG. 7 is a cross-sectional view showing a process of manufacturing the semiconductor memory device according to the first embodiment;

FIG. 8 is a cross-sectional view showing a process of manufacturing the semiconductor memory device according to the first embodiment;

FIG. 9 is a cross-sectional view showing a process of manufacturing the semiconductor memory device according to the first embodiment;

FIG. 10 is a cross-sectional view showing a process of manufacturing the semiconductor memory device according to a second embodiment of the present invention;

FIG. 11 is a cross-sectional view showing a process of manufacturing the semiconductor memory device according to the second embodiment;

FIG. 12 is a cross-sectional view showing a process of manufacturing the semiconductor memory device according to the second embodiment;

FIG. 13 is a cross-sectional view showing a process of manufacturing the semiconductor memory device according to a third embodiment of the present invention; and

FIG. 14 is a schematic diagram showing a method of manufacturing the semiconductor memory device according to the third embodiment.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

A semiconductor memory device and a method of manufacturing the same according to embodiments of the present invention will be described below with reference to the attached drawings. The semiconductor memory device is exemplified by a DRAM (Dynamic Random Access Memory) having a memory cell (DRAM cell) including a capacitor. In manufacturing the DRAM, the salicide technique is employed. Described below is an example where CoSi (Cobalt silicide) is formed as silicide. It should be noted that the silicide formed is not limited to CoSi. Other silicide such as NiSi (nickel silicide) and the like can be used.

### 1. First Embodiment

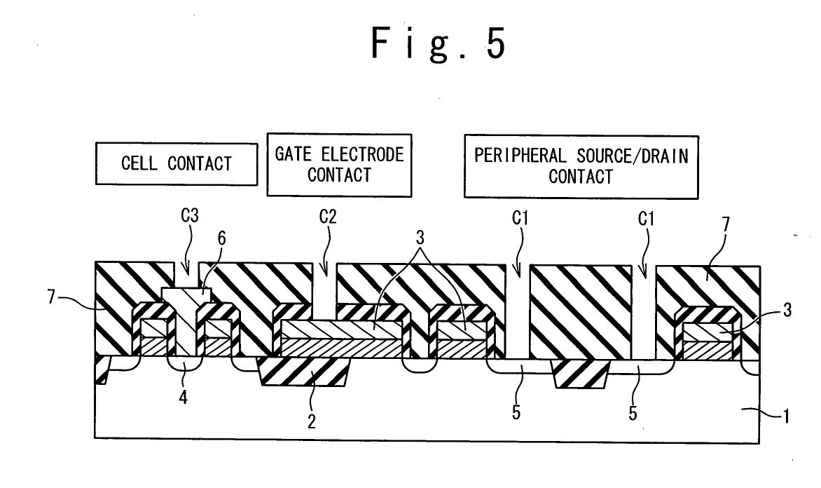

FIGS. 5 to 9 are cross-sectional views showing a process of manufacturing a semiconductor memory device according to the first embodiment.

Referring to FIG. 5, an isolation structure 2 such as an STI and the like is formed in a substrate 1. After that, gate electrodes 3 are formed on the substrate 1 through gate insulating films. The gate electrodes 3 include a gate electrode of a select transistor (memory transistor, cell-access transistor) included in a DRAM cell and a gate electrode of a peripheral transistor (logic transistor) included in a logic circuit. The gate electrode 3 has a polycide gate structure consisting of polysilicon and WSi (tungsten silicide). After that, a source/drain diffusion layer 4 of the select transistor and a source/drain diffusion layer 5 of the peripheral transistor are formed in the substrate 1 by using the gate electrodes 3 as a mask. As described above, the select transistor of the DRAM cell and the peripheral transistor included in the logic circuit are formed on the substrate 1.

Next, an interlayer insulating film 7 is blanket deposited. Then, a cell contact plug 6 is formed on the source/drain diffusion layer 4 of the select transistor in the DRAM cell. The cell contact plug 6 is made of doped polysilicon or doped amorphous silicon. The cell contact plug 6 is a part of a plug for connecting between the source/drain diffusion layer 4 and a capacitor of the DRAM cell or between the source/drain diffusion layer 4 and a bit line.

Next, an interlayer insulating film 7 is further blanket deposited so as to cover the cell contact plug 6. After that, a first contact hole C1, a second contact hole C2 and a third contact hole C3 are formed by using the photolithography technique. More specifically, after a resist mask having a predetermined pattern is formed on the interlayer insulating film 7, the interlayer insulating film 7 in a predetermined region is removed by dry etching. As a result, the first contact hole C1 contacting the source/drain diffusion layer 5 of the peripheral transistor is formed in a region where the peripheral transistor is formed. Moreover, the second contact hole C2 contacting the gate electrode 3 is formed. Here, the second contact holes C2 are so formed to contact respective gate electrodes 3 of the peripheral transistor and the select transistor. Furthermore, the third contact hole C3 contacting the cell contact plug 6 is formed in a region where the DRAM cell is formed.

It should be noted here that the cell contact plug 6 is formed on the substrate 1. Therefore, the bottom of the third contact hole C3 is located at a shallower level than the bottom of the first contact hole C1. In other words, the surface of the substrate 1 is located nearer to the bottom of the first contact hole C1 than to the bottom of the third contact hole C3. In addition, it is assumed in the explanation below that the second contact hole C2 denotes the contact hole contacting the gate electrode 3 of the select transistor. The same can be applied to a case of the gate electrode 3 of the peripheral transistor.

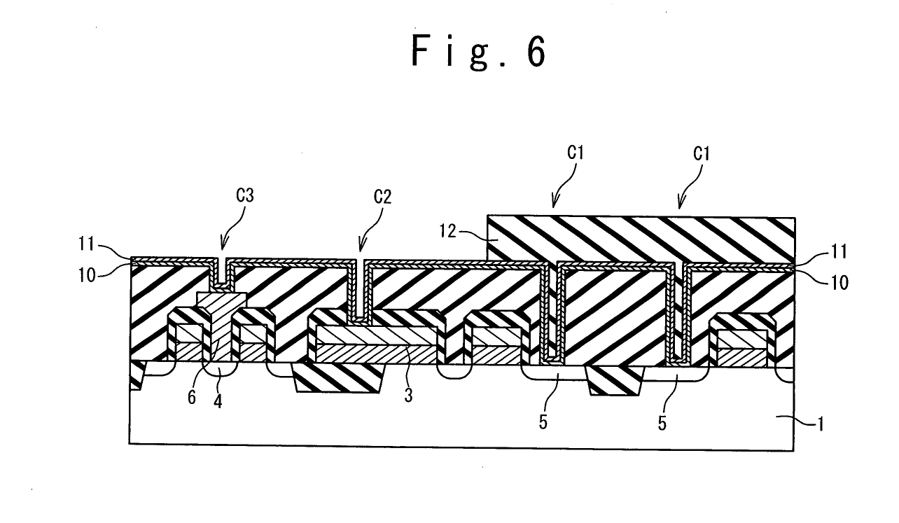

Next, as shown in FIG. 6, a Co film 10 as the material of CoSi is blanket deposited by a sputtering method. Then, in order to prevent oxidation of the Co film 10, a Ti film 11 is blanket deposited as a cap film. Subsequently, a resist mask 12 having a predetermined pattern is formed on the Ti film 11 by means of the photolithography technique. Here, the resist mask 12 is so formed selectively as to cover the first contact hole C1. In other words, the resist mask 12 is selectively formed over the region where the peripheral transistor is formed. The resist mask 12 is not formed over the second contact hole C2 and the third contact hole C3.

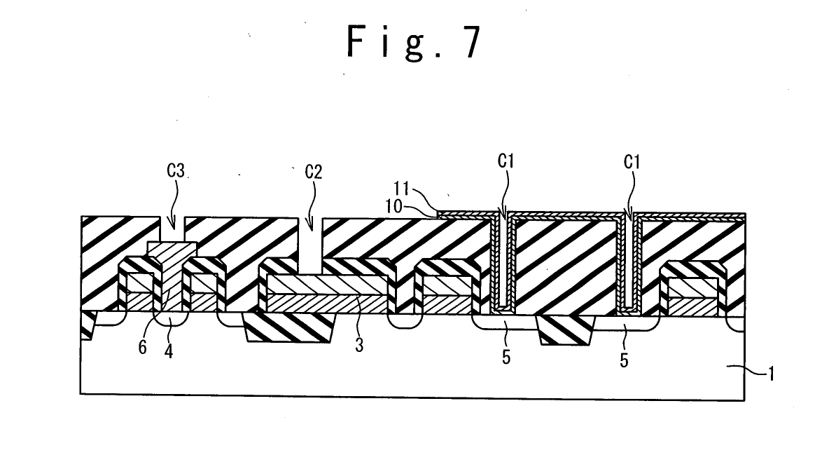

Next, the Ti film 11 and the Co film 10 are selectively removed through a dry etching process or a wet etching process using the above-mentioned resist mask 12. Since the resist mask 12 is formed over the first contact hole C1, the Ti film 11 and the Co film 10 over the first contact hole C1 are not removed. On the other hand, the Co film 10 and the Ti film 11 over the cell contact plug 6 and the gate electrode 3 are removed. When the resist mask 12 is removed, the structure shown in FIG. 7 is obtained.

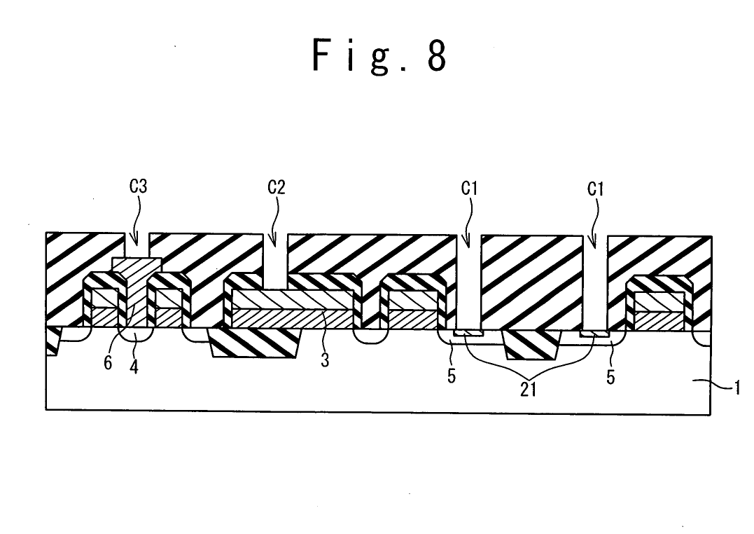

Next, a heat treatment at a temperature of about 400 degrees centigrade is performed, and thereby a silicide reaction occurs. When the remaining Co film 10 and the Ti film 11 as the cap film are removed by using mixed acid and the like, the structure shown in FIG. 8 is obtained. In FIG. 8, CoSi 21 is formed at the bottom of the first contact hole C1 in the region where the peripheral transistor is formed. On the other hand, silicide is not formed at the bottoms of the second contact hole C2 and the third contact hole C3. That is to say, the CoSi 21 is selectively formed at the bottom of only the first contact hole C1 out of the first to third contact holes C1 to C3.

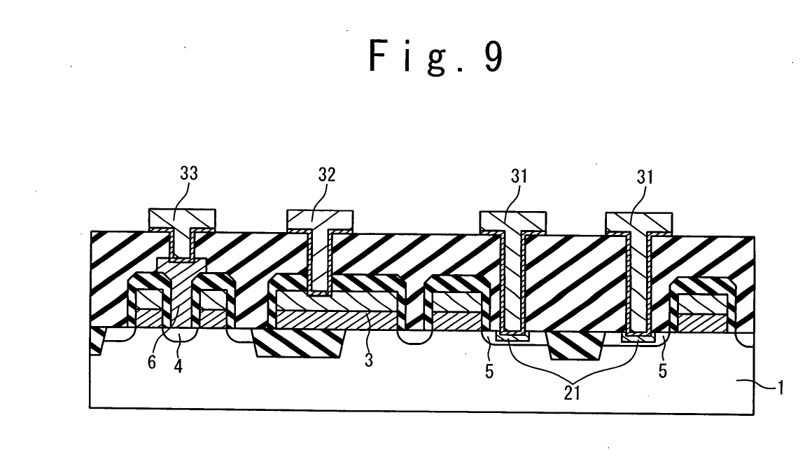

Next, as shown in FIG. 9, the contact hole C1 in the peripheral transistor region is filled with a first contact plug 31 connected to the CoSi 21. The first contact plug 31 and the CoSi 21 serve as a contact (first contact) that connects between the source/drain diffusion layer 5 of the peripheral transistor and an upper layer interconnection. Moreover, the contact hole C2 on the gate electrode 3 of the select transistor (and the peripheral transistor) is filled with a second contact plug 32 connected to a word line (upper layer interconnection). The second contact plug 32 serves as a contact (second contact) that connects between the gate electrode 3 and the word line. Furthermore, the contact hole C3 on the cell contact plug 6 of the select transistor is filled with a third contact plug 33 connected to the cell contact plug 6. Silicide is not formed between the cell contact plug 6 and the third contact plug 33. The third contact plug 33 and the cell contact plug 6 serve as a contact (third contact) that connects between the diffusion layer 4 of the select transistor and the bit line or the capacitor of the DRAM cell. Each of the first to third contact plugs 31 to 33 has a lamination structure of W/TiN/Ti.

After that, the capacitor of the DRAM cell is formed to be connected to the third contact plug 33. Moreover, the word line, the bit line and the upper layer interconnection having a predetermined pattern are formed.

According to the present embodiment, as described above, the CoSi 21 is selectively formed only in the first contact hole C1 out of the first contact hole C1, the second contact hole C2 and the third contact hole C3. As a result, the contact resistance of the first contact connected to the diffusion layer 5 of the peripheral transistor is reduced. Moreover, the silicide is not formed at the bottom of the second contact hole C2 contacting the gate electrode 3. Therefore, the increase in the contact resistance due to the increase in the number of interfaces can be prevented. Furthermore, the silicide is not formed at the bottom of the third contact hole C3. Therefore, the increase in the contact resistance due to the aggregation can be prevented. In this manner, it is possible to reduce the contact resistance as a whole according to the present embodiment.

### 2. Second Embodiment

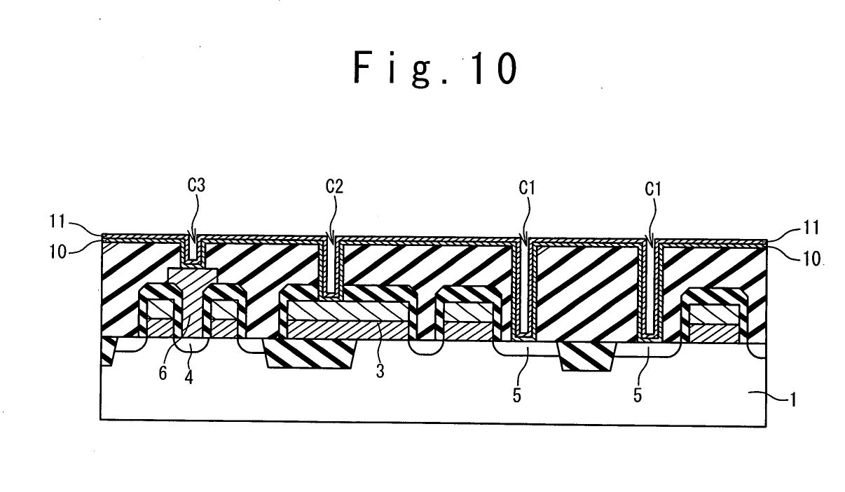

FIGS. 10 to 12 are cross-sectional views showing a process of manufacturing the semiconductor memory device according to the second embodiment. In the second embodiment, the same process as in the first embodiment is first carried out so that the structure shown in FIG. 5 is obtained.

Next, as shown in FIG. 10, a Co film 10 as the material of CoSi is blanket deposited by a sputtering method. Then, in order to prevent oxidation of the Co film 10, a Ti film 11 is blanket deposited as a cap film.

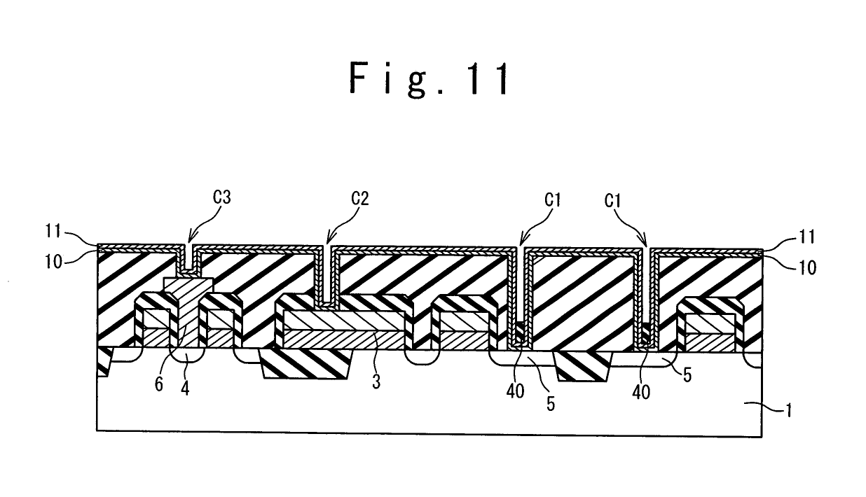

Next, a surface of the Co/Ti film is blanket coated with a positive resist. The positive resist becomes soluble when light is irradiated thereon. Next, an entire surface exposure process is performed without using a reticle. It should be noted here that since the cell contact plug 6 is formed on the substrate 1 as described above, the bottom of the first contact hole C1 is located at a deeper level than the bottoms of the second contact hole C2 and the third contact hole C3. It is therefore possible to control the light exposure such that the light reaches only the bottoms of the second contact hole C2 and the third contact hole C3 out of the first to third contact holes C1 to C3. In other words, it is possible to perform the exposure process such that the property of the positive resist at the bottom of the first contact hole C1 is not changed. In a process of dissolving the positive resist, only the positive resist in the select transistor region of the DRAM cell, namely, only the positive resist that is irradiated with the light is removed. Consequently, as shown in FIG. 11, a resist mask 40 is selectively formed only in the first contact hole C1.

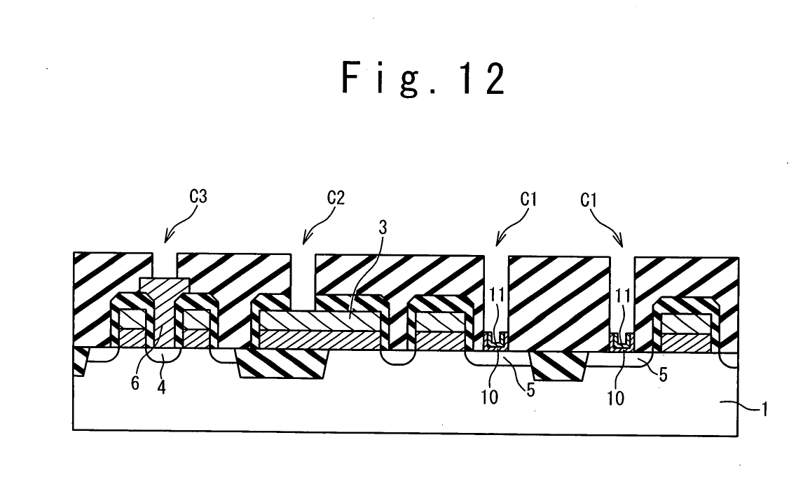

Next, the Ti film 11 and the Co film 10 are selectively removed through a dry etching process or a wet etching process using the above-mentioned resist mask 40. Since the resist mask 40 is formed at the bottom of the first contact hole C1, the Ti film 11 and the Co film 10 at the bottom of the first contact hole C1 are not removed. On the other hand, the Co film 10 and the Ti film 11 over the cell contact plug 6 and the gate electrode 3 are removed. When the resist mask 40 is removed, the structure shown in FIG. 12 is obtained.

After that, a heat treatment at a temperature of about 400 degrees centigrade is performed, as in the first embodiment. As a result, the CoSi 21 is selectively formed at the bottom of only the first contact hole C1 out of the first to third contact holes C1 to C3, as shown in the foregoing FIG. 8. Subsequently, as shown in FIG. 9, the first to third contact plugs 31 to 33 are formed in the first to third contact holes C1 to C3, respectively.

According to the second embodiment mentioned above, the same effect as in the first embodiment can be obtained. Furthermore, an additional effect that a microfabrication process is facilitated can be obtained, because the photo resist can be patterned without using a reticle.

### 3. Third Embodiment

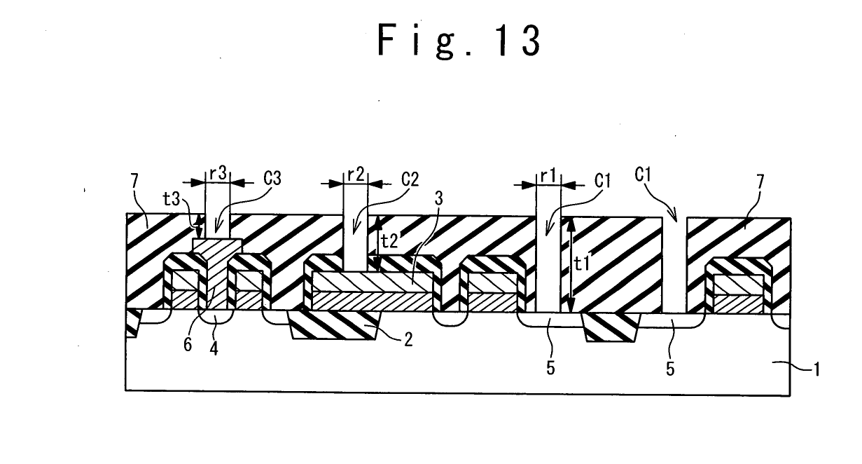

In the third embodiment, the same process as in the first embodiment is first carried out so that the structure shown in FIG. 5 is obtained. Here, as shown in FIG. 13, hole diameters of the first contact hole C1, the second contact hole C2 and the third contact hole C3 are r1, r2 and r3, respectively. Depths of the first contact hole C1, the second contact hole C2 and the third contact hole C3 are t1, t2 and t3, respectively.

Next, as shown in the foregoing FIG. 10, the Co film 10 as the material of CoSi is blanket deposited by a sputtering method. Then, in order to prevent oxidation of the Co film 10, the Ti film 11 is blanket deposited as a cap film.

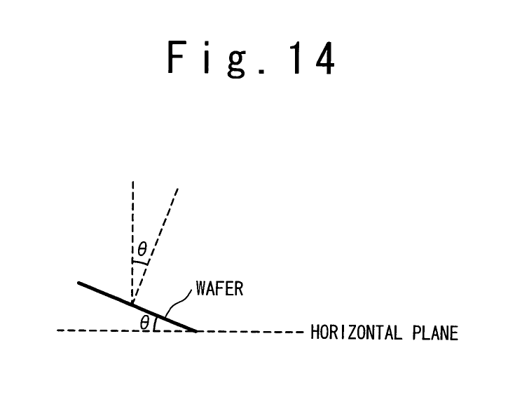

Next, as shown in FIG. 14, a wafer is tilted by an angle θ from a horizontal plane. Here, the angle θ is set to satisfy the following equation (1):
r1/t1<tan θ≦r2/t2≦r3/t3 (1)

When a sputter etching is performed under the condition, the Co film 10 and the Ti film 11 are partially sputter-etched. More specifically, the Co film 10 and the Ti film 11 are removed from the bottoms of the second contact hole C2 and the third contact hole C3, while the Co film 10 and the Ti film 11 are not removed from the bottom of the first contact hole C1. That is to say, it is possible to leave the metal film only at the bottom of the first contact hole C1 (see FIG. 12).

After that, a heat treatment at a temperature of about 400 degrees centigrade is performed, as in the first embodiment. As a result, the CoSi 21 is selectively formed at the bottom of only the first contact hole C1 out of the first to third contact holes C1 to C3, as shown in the foregoing FIG. 8. Subsequently, as shown in FIG. 9, the first to third contact plugs 31 to 33 are formed in the first to third contact holes C1 to C3, respectively.

According to the third embodiment mentioned above, the same effect as in the first embodiment can be obtained. Furthermore, it is not necessary to employ the photolithography technique for selectively forming the silicide only at the bottom of the first contact hole C1. Therefore, an additional effect that the manufacturing process is simplified can be obtained.

It is apparent that the present invention is not limited to the above embodiment and may be modified and changed without departing from the scope and spirit of the invention.

What is claimed is:

1. A semiconductor memory device comprising:
a memory cell formed on a substrate; and
a peripheral transistor formed on said substrate,
wherein said memory cell has:
a select transistor formed on said substrate; and
a capacitor connected to said select transistor,
wherein a diffusion layer of said peripheral transistor is connected to an upper layer interconnection through a first contact,
gate electrodes of said peripheral transistor and said select transistor are connected to upper layer interconnections through respective of second contacts,
a diffusion layer of said select transistor is connected to any of a bit line and said capacitor through a third contact, and
silicide is selectively formed only in said first contact out of said first contact, said second contacts and said third contact.

2. The semiconductor memory device according to claim 1,
wherein said silicide is formed at a bottom of said first contact.

3. The semiconductor memory device according to claim 2,
wherein said third contact includes:
a first plug formed on said diffusion layer of said select transistor; and
a second plug formed on said first plug without through said silicide,
wherein a surface of said substrate is located nearer to a bottom of said first contact than to a bottom of said second plug.

4. The semiconductor memory device according to claim 1,
wherein said silicide is cobalt silicide.
